(19) United States
(12) Patent Application Publication
(10) Pub. No.: US 2007/0048997 A1
(43) Pub. Date: Mar. 1, 2007

(54) Chip package structure and method for manufacturing bumps

(76) Inventor: Jiunheng Wang, Tainan County (TW)

Correspondence Address: J.C. Patents, Inc.;Suite 250, 4 Venture, Irvine, CA, 92618, US

(21) Appl. No.: 11/302,610

(22) Filed: Dec. 13, 2005

(30) Foreign Application Priority Data
Aug. 31, 2005 (TW) 94129919

(51) Int. Cl. H01L 21/44

(52) U.S. Cl. 438/612

(57) ABSTRACT

A method for manufacturing bumps is provided. First, a first metal layer is formed on a substrate. Then, a patterned second metal layer is formed on the first metal layer. Then, flat bumps are formed on the second metal layer. Finally, the first metal layer is patterned to form bond pads and traces connected to the bond pads.

### CROSS-REFERENCE TO RELATED APPLICATION

This application claims the priority benefit of Taiwan application serial no. 94129919, filed on Aug. 31, 2005. All disclosure of the Taiwan application is incorporated herein by reference.

### BACKGROUND OF THE INVENTION

1. Field of the Invention

The present invention relates to a method for manufacturing bumps. More particularly, the present invention relates to a chip package structure and a method for manufacturing bumps.

2. Description of the Related Art

In the past few years, the emission efficiency of light emitting diodes (LED) has improved so much that fluorescent lamps and incandescent light bulbs are replaced by LEDs in certain application areas. For example, there are the high-response light source of a scanner, the back light of liquid crystal display or the illumination of the instrument panel on the front dash board of a car, traffic lights and general illumination devices. The light emitting diode has a great number of advantages over a conventional light bulb including, for example, smaller volume, longer lifetime, lower driving voltage/current, durability, less heat generated in operation, mercury-free and high emission efficiency.

FIG. 1 is a schematic cross-sectional view of one type of conventional light emitting diode (LED) chip package structure. Referring to FIG. 1, the LED chip package structure 100 comprises a substrate 110, stud bumps 120 and an LED chip 130. The substrate 110 is a ceramic substrate and has first bond pads 112. The chip 130 is disposed on the substrate 110 and the stud bumps 120 are disposed between the chip 130 and the substrate 110 for electrically connecting the chip 130 and the substrate 110. In addition, the chip 130 has second bond pads 132 such that the bump studs 120 are located between the first bond pads 112 and the second bond pads 132.

It should be noted that the method of forming the stud bumps 120 over the first bond pads 112 includes applying the wire-bonding technique. More specifically, wire-bonding equipment is used to form a stud bump 120 on a corresponding bond pad 112 and then the metal lead wires are cut off. However, the stud bumps 120 are fixed to the first bond pads 112 through ultrasonic vibration. Hence, the bonding strength between the stud bumps 120 and the corresponding first bond pad 112 is rather poor. Furthermore, the size and height of each stud bump 120 formed by the aforementioned method will not be uniform. As a result, the bonding strength between the stud bumps 120 and the chip 130 will be affected.

### SUMMARY OF THE INVENTION

Accordingly, at least one objective of the present invention is to provide a manufacturing method capable of producing bumps with a uniform height.

At least another objective of the present invention is to provide a chip package structure with a stronger bonding strength between its chip and its substrate.

To achieve these and other advantages and in accordance with the purpose of the invention, as embodied and broadly described herein, the invention provides a method for manufacturing bumps. First, a first metal layer is formed on a substrate. Then, a patterned second metal layer is formed on the first metal layer. Then, flat bumps are formed on the second metal layer. Finally, the first metal layer is patterned to form bond pads and traces connected to the bond pads.

According to one embodiment of the present invention, the method of forming the flat bumps includes the following steps. First, a patterned photoresist layer is formed over the substrate. The patterned photoresist layer exposes a portion of the patterned second metal layer. Then, the flat bumps are formed over the patterned second metal layer exposed through the patterned photoresist layer. Finally, the patterned photoresist layer is removed.

According to one embodiment of the present invention, the method of forming the flat bumps includes performing an electroplating process.

According to one embodiment of the present invention, the method of forming the patterned second metal layer includes the following steps. First, the second metal layer is formed over the first metal layer. The method of forming the second metal layer can be a sputtering process. Then, the second metal layer is patterned to form the patterned second metal layer.

According to one embodiment of the present invention, the method of forming the first metal layer can be a sputtering process.

According to one embodiment of the present invention, the substrate can be a ceramic substrate and the first metal layer can be a titanium/tungsten layer.

According to one embodiment of the present invention, the material constituting the patterned second metal layer and the flat bumps can be gold.

The present invention also provides a chip package structure comprising a substrate, a chip and flat bumps. The substrate has first bond pads and traces connected to the first bond pads. Furthermore, the first bond pads and the traces comprise the first metal layer and the second metal layer disposed thereon. The second metal layer has a thickness between 0.5 μm to 1 μm. In addition, each flat bump is disposed on the corresponding first bond pad. The chip having second bond pads thereon is disposed over the substrate. Each second bond pad on the chip is electrically connected to the corresponding first bond pad through the flat bump.

According to one embodiment of the present invention, the chip package structure further comprises a solder material disposed between each second bond pad and the corresponding flat bump. Furthermore, each second bond pad is electrically connected to the corresponding flat bump through the solder material.

According to one embodiment of the present invention, the chip package structure further comprises an adhesive material with two-stage property disposed between each second bonding pad and the corresponding flat bump. Furthermore, each second bond pad is electrically connected to the corresponding flat bump through the adhesive material.

According to one embodiment of the present invention, the substrate can be a ceramic substrate and the first metal layer can be a titanium/tungsten layer.

According to one embodiment of the present invention, the material constituting the patterned second metal layer and the flat bumps can be gold.

According to one embodiment of the present invention, the chip can a light emitting diode chip.

Accordingly, the flat bumps and the traces are simultaneously formed in the present invention to improve the low bonding strength between the stud bumps and the substrate as well as the large variation in the height of the bumps using the conventional wire-bonding technique.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a schematic cross-sectional view of one type of conventional light emitting diode (LED) chip package structure.

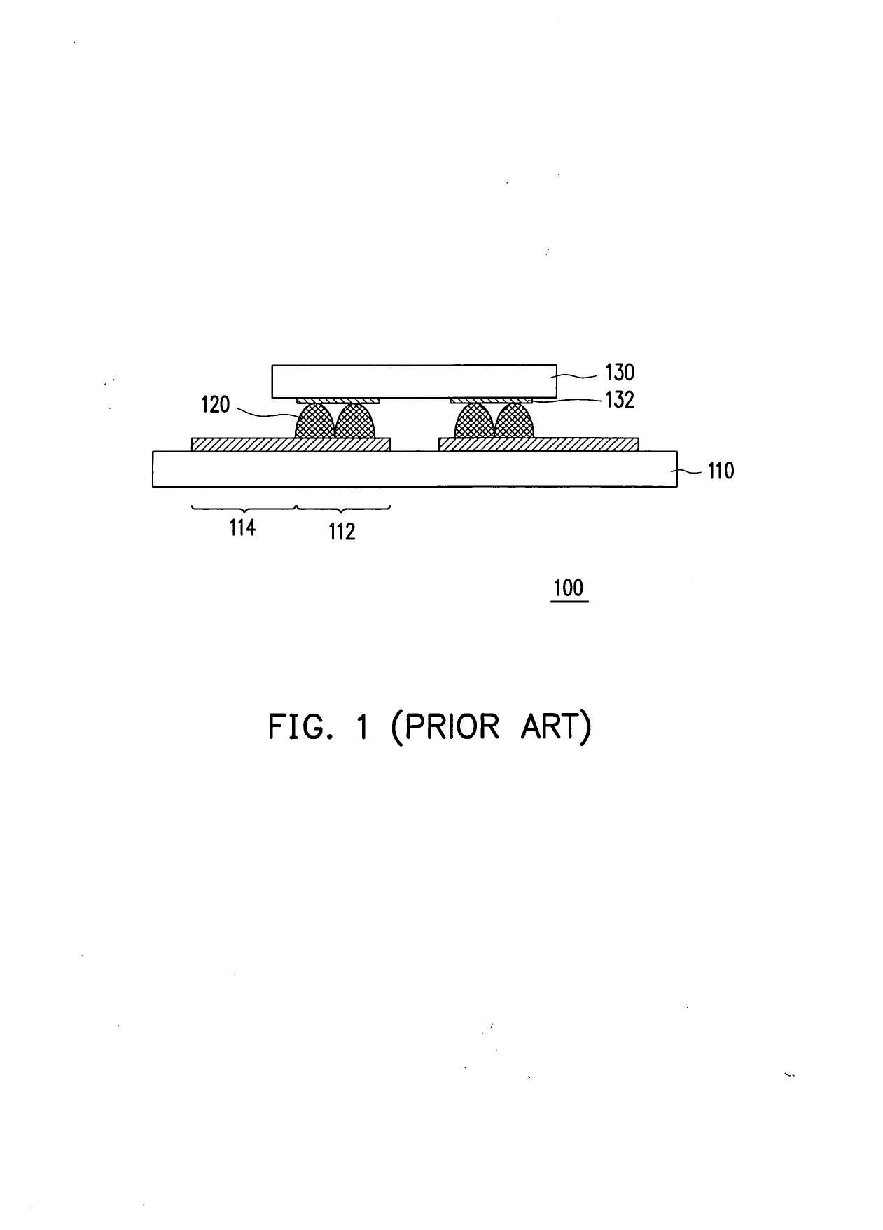

FIGS. 2A through 2D are schematic cross-sectional views showing the steps for manufacturing bumps according to one preferred embodiment of the present invention.

FIG. 3 is a schematic cross-sectional view of a chip package structure with bumps fabricated using the steps described in FIGS. 2A through 2D.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

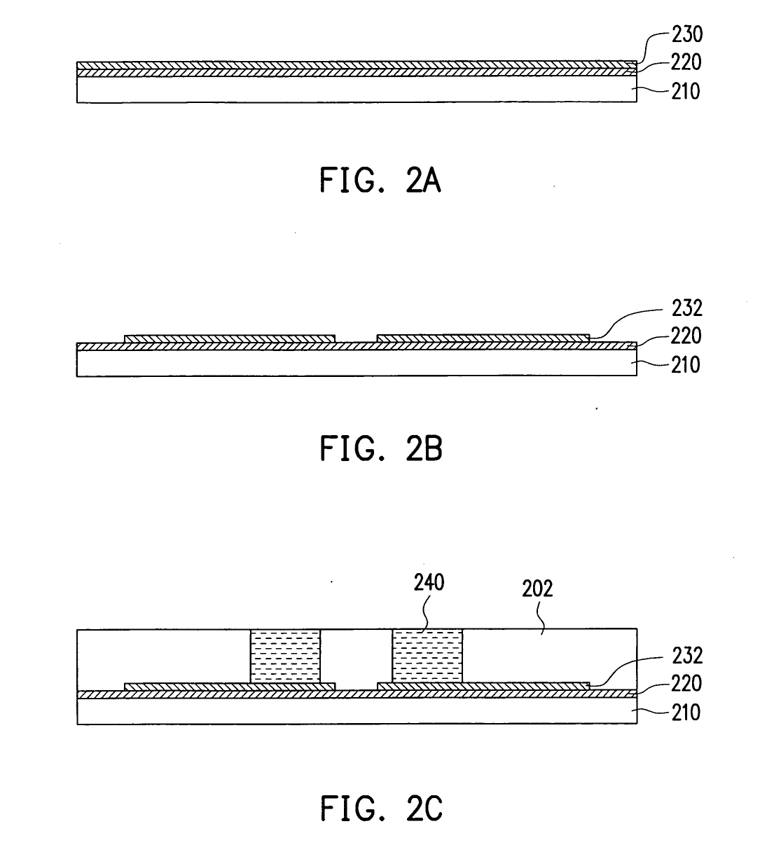

FIGS. 2A through 2D are schematic cross-sectional views showing the steps for manufacturing bumps according to one preferred embodiment of the present invention. As shown in FIG. 2A, the method of manufacturing bumps according to the present embodiment includes the following steps. First, a substrate 210 is provided. The substrate 210 can be a ceramic substrate or a substrate fabricated using other materials. Then, a first metal layer 220 is formed on the substrate 210. The first metal layer 220 can be a titanium/tungsten layer or other composite metal layer. The method of forming the first metal layer 220 can be a sputtering process or other suitable processes. Then, a second metal layer 230 is formed on the first metal layer 220. The method of forming the second metal layer 230 can be a sputtering process or other suitable processes.

As shown in FIG. 2B, a patterned second metal layer 232 is formed on the first metal layer 220. The patterned second metal layer 232 can be fabricated using gold or other suitable metal materials. The method of forming the patterned second metal layer 232 can be a patterning process on the second metal layer 230. The patterning process can be a photolithographic process and an etching processes.

As shown in FIG. 2C, the flat bumps 240 are formed on the patterned second metal layer 232. The flat bumps 240 and the patterned second metal layer 232 can be fabricated using the same material; and the flat bumps 240 can be fabricated using gold or other suitable metal materials. The method of forming the flat bumps 240 can be forming a patterned photoresist layer 202 over the substrate 210 such that the patterned photoresist layer 202 exposes a portion of the patterned second metal layer 232. Then, an electroplating process is carried out to form the flat bumps 240 on the patterned second metal layer 232 exposed by the patterned photoresist layer 202. Finally, the patterned photoresist layer 202 is removed.

As shown in FIG. 2D, the first metal layer 220 is patterned to form first bond pads 212 and traces 214 connected to the first bond pads 212 on the substrate 210. The flat bumps 240 are formed over the respective first bond pads 212.

The stud bumps formed by the conventional wire-bonding technique have geometric dimensions limited by the dimensions of the bonding wires. In the present invention, the flat bumps 240, the first bond pads 212 and the traces 214 are fabricated using a semiconductor process. Hence, not only are the geometric dimensions of the flat bumps 240 more uniform, but the first bond pads 212 and the traces 214 are also simultaneously formed together. In other words, the flat bumps 240 and the first bond pads 212 have a better bonding strength compared with the conventional technique. In addition, the circuit (the first bond pads 212 and the traces 214) on the substrate 210 and the flat bumps 240 can be formed simultaneously.

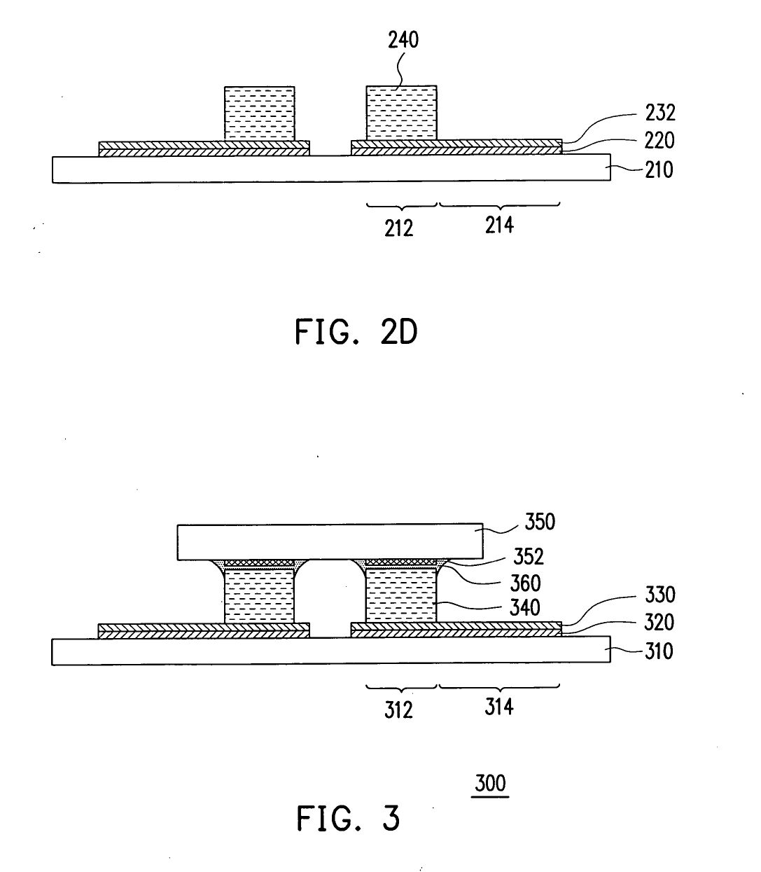

FIG. 3 is a schematic cross-sectional view of a chip package structure with bumps fabricated using the steps described in FIGS. 2A through 2D. Referring to FIG. 3, the chip package structure 300 comprises a substrate 310, flat bumps 340 and a chip 350. The substrate 310 can be a ceramic substrate or other material substrate. The substrate 310 has first bond pads 312 and traces 314 connected to the first bond pads 312. The first bond pads 312 and the traces 314 comprise a first metal layer 320 and a second metal layer 330 disposed thereon. Furthermore, the second metal layer 330 has a thickness between 0.5 μm to 1 μm. The second metal layer 330 can be fabricated using gold. The first metal layer 320 can be a titanium/tungsten layer or other suitable composite metal layer. Since the second metal layer 330 has a preferred thickness between 0.5 μm to 1 μm, the wire-bonding equipment can form a wire bond (not shown) on the second metal layer 330 without damaging the substrate 310.

The chip 350 is disposed on the substrate 310. The chip 350 has second bond pads 352. The flat bumps 340 are disposed between the first bond pads 312 and corresponding second bond pads 352. Furthermore, the second bond pads 352 of the chip 350 are electrically connected to the first bond pads 312 of the substrate 310 through the respective flat bumps 340. It should be noted that the method of forming the flat bumps 340 is not limited to the aforementioned process. Other processes may be used. In addition, the flat bumps 340 and the second metal layer 330 can be fabricated using the same material; and the flat bumps can be fabricated using gold. Moreover, the chip 350 can be a light emitting diode (LED) chip.

When the flat bumps 340 are fabricated from gold, ultrasonic vibration can be applied to the flat bumps 340 and the second bond pads 352 of the chip 350 so that the flat bumps 340 and the second bond pads 352 of the chip 350 are bonded together. However, the chip package structure 300 may further include a solder material 360 for electrically connecting the flat bumps 340 and the second bond pads 352 of the chip 350. Alternatively, an adhesive material with two-stage property can be coated on the second bond pads 352 of the chip 350. Then, the adhesive material is pre-cured so that the second bond pads 352 of the chip 350 can be electrically connected with the respective flat bumps 340 through the adhesive material.

In comparison with the geometrically limited stud bumps formed by the conventional wire-bonding technique, the flat bumps 340 formed by the process in the present invention can have a height that varies according to demand. Thus, the overall thickness of the chip package structure in the present invention can be reduced. Moreover, compared with the conventional technique, the bonding between the flat bumps 340 and the second metal layer 330 or between the flat bumps 340 and the second bond pads 352 of the chip 350 is more reliable.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of fabricating bumps, comprising the steps of:
providing a substrate;
forming a first metal layer on the substrate;
forming a patterned second metal layer on the first metal layer;
forming a plurality of flat bumps on the patterned second metal layer; and
patterning the first metal layer to form a plurality of bond pads and a plurality of traces connected to the respective flat bumps.

2. The method of claim 1, wherein the method of forming the flat bumps includes:
forming a patterned photoresist layer over the substrate, wherein the patterned photoresist layer exposes a portion of the patterned second metal layer;
forming the flat bumps on the patterned second metal layer exposed by the patterned photoresist layer; and
removing the patterned photoresist layer.

3. The method of claim 1, wherein the step of forming the flat bumps further includes performing an electroplating process.

4. The method of claim 1, wherein the method of forming the patterned second metal layer includes:
forming a second metal layer over the first metal layer; and
patterning the second metal layer to form the patterned second metal layer.

5. The method of claim 4, wherein the step of forming the second metal layer includes performing a sputtering process.

6. The method of claim 1, wherein the step of forming the first metal layer includes performing a sputtering process.

7. The method of claim 1, wherein the substrate includes a ceramic substrate.

8. The method of claim 1, wherein the first metal layer includes a titanium/tungsten layer.

9. The method of claim 1, wherein the material constituting the patterned second metal layer and the flat bumps includes gold.

10. A chip package structure, comprising:
a substrate having a plurality of first bond pads and a plurality of traces connected to the respective first bond pads with the first bond pads and the traces comprising a first metal layer and a second metal layer disposed thereon, wherein the second metal layer has a thickness between about. 0.5 μm to 1 μm;
a plurality of flat bumps disposed on the respective first bond pads; and
a chip disposed on the substrate and a plurality of second bond pads disposed on the chip, wherein the second bond pads of the chip are electrically connected to corresponding first bond pads on the substrate through the flat bumps.

11. The chip package structure of claim 10, wherein the package structure further includes a solder material disposed between the second bond pads and their corresponding flat bumps such that the second bond pads are electrically connected to the flat bumps through the solder material.

12. The chip package structure of claim 10, wherein the package structure further includes an adhesive material with two-stage property disposed between the second bonding pads and their corresponding flat bumps such that the second bond pads are electrically connected to the flat bumps through the adhesive material.

13. The chip package structure of claim 10, wherein the substrate includes a ceramic substrate.

14. The chip package structure of claim 10, wherein the first metal layer includes a titanium/tungsten layer.

15. The chip package structure of claim 10, wherein the material constituting the second metal layer and the flat bumps includes gold.

16. The chip package structure of claim 10, wherein the chip includes a light emitting diode (LED) chip.
